(19) United States
(12) Patent Application Publication
(10) Pub. No.: US 2025/0203823 A1
(43) Pub. Date: Jun. 19, 2025

(54) SERVER AND HEAT DISSIPATION MODULE

(71) Applicant: WISTRON CORP., New Taipei City (TW)

(72) Inventors: Wen Hua Zhang, New Taipei City (TW); I CHEN HSU, New Taipei City (TW); Cheng Ying Wu, New Taipei City (TW); Kuo-hua Peng, New Taipei City (TW); CHIEN-JUNG CHIU, New Taipei City (TW)

(21) Appl. No.: 18/636,512

(22) Filed: Apr. 16, 2024

(30) Foreign Application Priority Data
Dec. 14, 2023 (TW) 112148757

(51) Int. Cl. H05K 7/20

(52) U.S. Cl. CPC H05K 7/20809; H05K 7/20409

(57) ABSTRACT

A heat dissipation module includes a plurality of thermally conductive components and a first heat dissipation fin assembly. Each of the thermally conductive components includes a heat absorption portion and a first condensation portion. The first condensation portion includes a first connection portion and a first bent portion, and two ends of the first connection portion are respectively connected to the first bent portion and the heat absorption portion. The first heat dissipation fin assembly is connected to the first bent portion of the first condensation portion of each of the thermally conductive components.

### CROSS-REFERENCE TO RELATED APPLICATIONS

This non-provisional application claims priority under 35 U.S.C. § 119 (a) on Patent Application No(s). 112148757 filed in Taiwan, R.O.C. on Dec. 14, 2023, the entire contents of which are hereby incorporated by reference.

### TECHNICAL FIELD

The disclosure relates to a server and a heat dissipation module.

### BACKGROUND

As Artificial Intelligence (i.e., AI) technology progresses, servers for AI need to be equipped with memories of higher performance to meet requirements. However, memories with higher performance generate more heat. Especially in servers, those memories are in a compact arrangement, and thus heat generated by these memories is easy to accumulate and difficult to be dissipated. As a result, the performance of these memories may be reduced due to excessive temperatures, or the memories may be damaged. Therefore, how to effectively dissipate heat generated by these memories which are in the compact arrangement is one of the crucial topics in this field.

### SUMMARY

The disclosure provides a server and a heat dissipation module which are capable of dissipating heat generated by the memories which are in the compact arrangement.

One embodiment of the disclosure provides a server. The server includes a casing, a motherboard, a plurality of plate-shaped heat sources and a heat dissipation module. The motherboard is disposed in the casing. The plate-shaped heat sources are separately disposed on the motherboard. The heat dissipation module includes a plurality of thermally conductive components and a first heat dissipation fin assembly. Each of the thermally conductive components includes a heat absorption portion and a first condensation portion. The heat absorption portion of each of the thermally conductive components and the plate-shaped heat sources are alternately arranged, and the heat absorption portion of each of the thermally conductive components is connected to the plate-shaped heat sources. The first condensation portion includes a first connection portion and a first bent portion. Two ends of the first connection portion are respectively connected to the first bent portion and the heat absorption portion. The first heat dissipation fin assembly is connected to the first bent portion of the first condensation portion of each of the plurality of thermally conductive components.

Another embodiment of the disclosure provides a heat dissipation module. The heat dissipation module includes a plurality of thermally conductive components and a first heat dissipation fin assembly. Each of the thermally conductive components includes a heat absorption portion and a first condensation portion. The first condensation portion includes a first connection portion and a first bent portion, and two ends of the first connection portion are respectively connected to the first bent portion and the heat absorption portion. The first heat dissipation fin assembly is connected to the first bent portion of the first condensation portion of each of the thermally conductive components.

According to the server and the heat dissipation module, the thermally conductive components includes the heat absorption portions for enabling the heat absorption portions of the thermally conductive components to be alternately arranged with the plate-shaped heat sources arranged compactly and to be connected to the plate-shaped heat sources. Therefore, heat generated by the plate-shaped heat sources can be conducted to the heat absorption portions of the thermally conductive components and then conducted to the first heat dissipation fin assembly via the first condensation portions of the thermally conductive components, such that the first heat dissipation fin assembly can perform heat exchange with air via its large surface area so as to take heat away, thereby effectively cooling the plate-shaped heat sources.

### BRIEF DESCRIPTION OF THE DRAWINGS

The present disclosure will become better understood from the detailed description given herein below and the accompanying drawings which are given by way of illustration only and thus are not intending to limit the present disclosure and wherein:

FIG. 1 is a partial perspective view of a server according to a first embodiment of the disclosure;

FIG. 2 is a partial and enlarged exploded view of the server in FIG. 1;

FIG. 3 is a side view of a motherboard and plate-shaped heat sources in FIG. 2;

FIG. 4 is a schematic view of a heat dissipation module in FIG. 2;

FIG. 5 is a side view of a thermally conductive component in FIG. 4;

FIG. 6 is a side view of the motherboard, the plate-shaped heat sources and the heat dissipation module in FIG. 2;

FIG. 7 is a partial perspective view of a server according to a second embodiment of the disclosure;

FIG. 8 is a partial and enlarged exploded view of the server in FIG. 7;

FIG. 9 is a cross-sectional view of a motherboard, plate-shaped heat sources and a heat dissipation module in FIG. 8; and

FIG. 10 is a schematic view of a motherboard, a plate-shaped heat source and a heat dissipation module according to a third embodiment of the disclosure.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

In addition, the terms used in the present disclosure, such as technical and scientific terms, have its own meanings and can be comprehended by those skilled in the art, unless the terms are additionally defined in the present disclosure. That is, the terms used in the following paragraphs should be read on the meaning commonly used in the related fields and will not be overly explained, unless the terms have a specific meaning in the present disclosure.

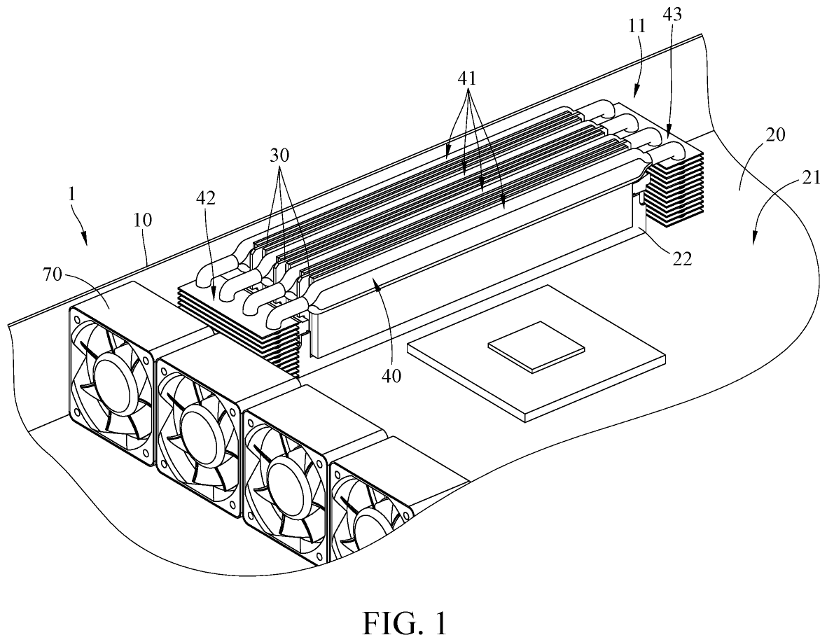

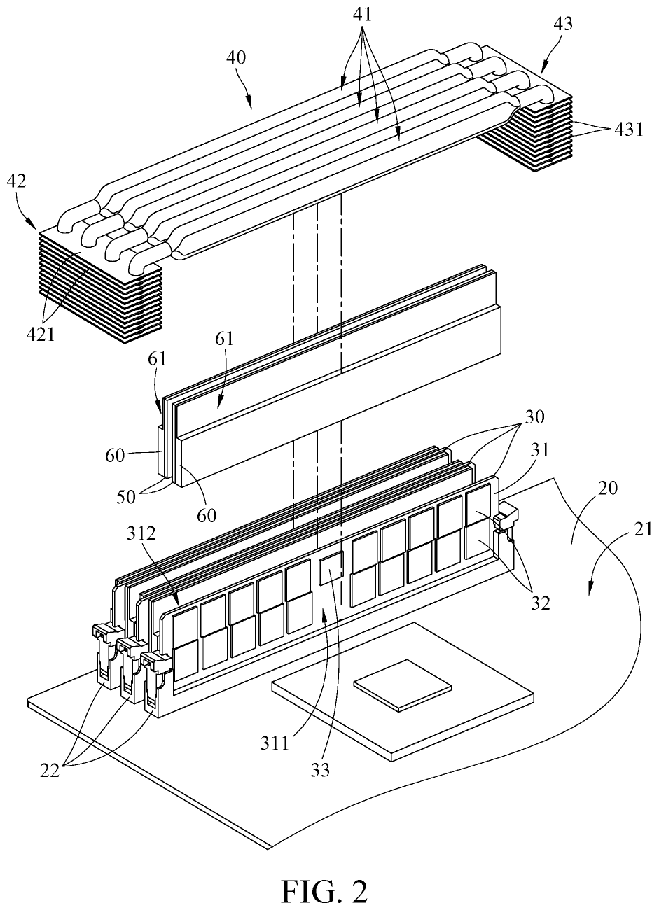

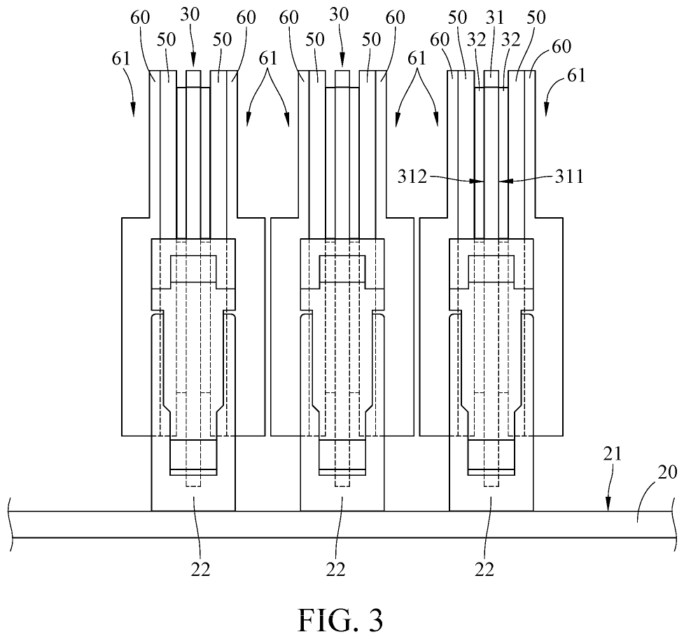

Referring to FIGS. 1 to 3, FIG. 1 is a partial perspective view of a server 1 according to a first embodiment of the disclosure, FIG. 2 is a partial and enlarged exploded view of the server 1 in FIG. 1, and FIG. 3 is a side view of a motherboard 20 and plate-shaped heat sources 30 in FIG. 2.

In this embodiment, the server 1 is, for example, a 1U server. The server 1 includes a casing 10, a motherboard 20, a plurality of plate-shaped heat sources 30 and a heat dissipation module 40. In addition, the server 1 may further include a plurality of thermal interface materials 50, a plurality of metal sheets 60 and a plurality of fans 70. Note that the server 1 may further include other devices or modules, such as expansion card module, hard disk drive module, a power supply and so on. However, in order to clearly show the relative position relationship among the motherboard 20, the plate-shaped heat sources 30, the heat dissipation module 40 and the fans 70, the aforementioned devices or modules are omitted in the figures.

The casing 10 has an accommodation space 11, and the motherboard 20 is disposed in the accommodation space 11 of the casing 10. The motherboard 20 has a support surface 21 and a plurality of sockets 22. The sockets 22 are disposed on the support surface 21, and the sockets 22 are parallel to one another. The plate-shaped heat sources 30 are, for example but not limited to, DDR5 memories or memories of higher levels. The plate-shaped heat sources 30 are inserted into the sockets 22 of the motherboard 20 so as to be electrically connected to circuits of the motherboard 20, and the plate-shaped heat sources 30 are spaced apart from one another and are parallel to one another. The plate-shaped heat sources 30 are, for example, the same in structure, and thus the following description only specifically introduce one of them. The plate-shaped heat source 30 includes a circuit board 31, a plurality of chips 32 (e.g., memory chips) and a power management unit 33 (e.g., a power management IC). The circuit board 31 has a first surface 311 and a second surface 312 which are located opposite to each other and face two opposite directions, respectively. Some of the chips 32 and the power management unit 33 are disposed on the first surface 311 of the circuit board 31, and the others of the chips 32 are disposed on the second surface 312 of the circuit board 31.

Two opposite sides of each of the plate-shaped heat source 30 are provided with two metal sheets 60 and two thermal interface materials 50, respectively. Specifically, taking one plate-shaped heat source 30, two metal sheets 60 and two thermal interface materials 50 as one set for instance, one of the two thermal interface materials 50 is clamped between one of the two metal sheets 60 and the first surface 311 of the circuit board 31 so as to be thermally coupled with the chips 32 and the power management unit 33 on the first surface 311 and this metal sheet 60, and the other one of the thermal interface materials 50 is clamped between the other one of the metal sheets 60 and the second surface 312 of the circuit board 31 so as to be thermally coupled with the chips 32 on the second surface 312 and this metal sheet 60. Each of the metal sheets 60 has an installation recess 61.

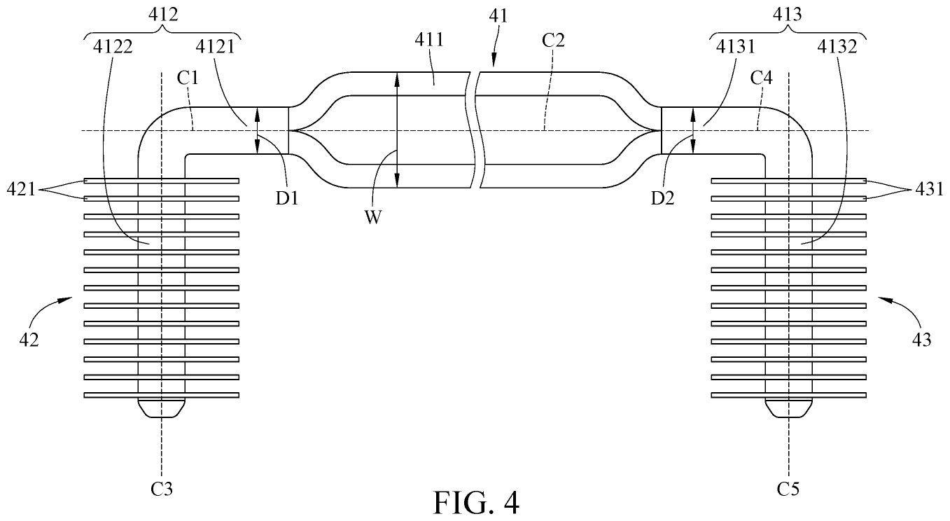

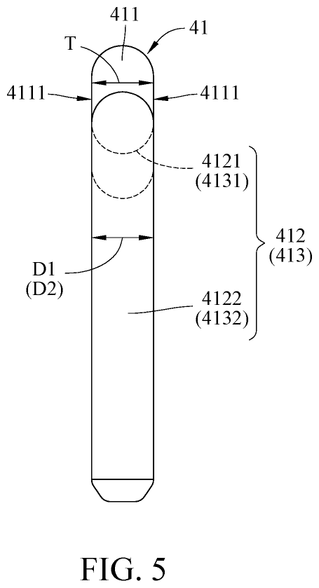

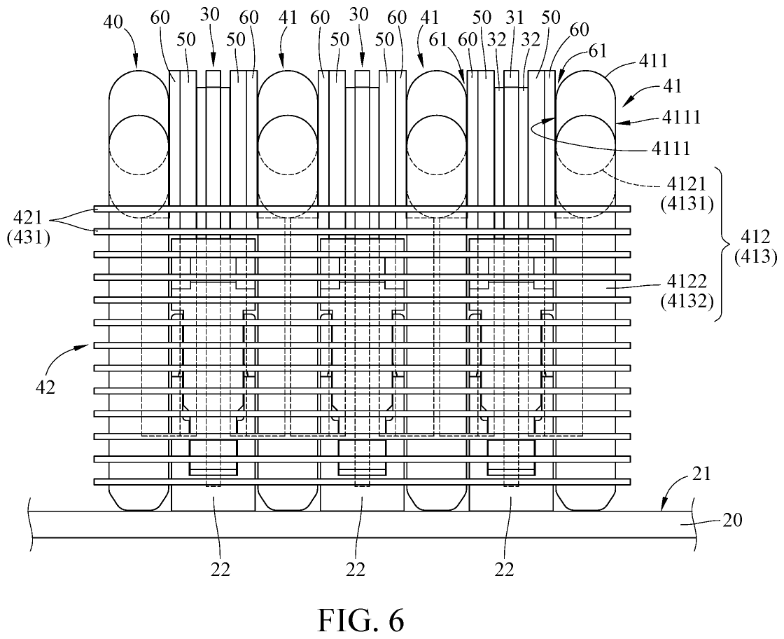

Then, referring to FIGS. 4 to 6, FIG. 4 is a schematic view of the heat dissipation module 40 in FIG. 2, FIG. 5 is a side view of the thermally conductive component 41 in FIG. 4, and FIG. 6 is a side view of the motherboard 20, the plate-shaped heat sources 30 and the heat dissipation module 40 in FIG. 2.

The heat dissipation module 40 includes a plurality of thermally conductive components 41 and a first heat dissipation fin assembly 42. In addition, the heat dissipation module 40 may further include a second heat dissipation fin assembly 43.

Each of the thermally conductive components 41 is, for example, a heat pipe made of a single piece. The thermally conductive components 41 are the same in structure, and the following descriptions only specifically introduce of them. The thermally conductive component 41 includes a heat absorption portion 411, a first condensation portion 412 and a second condensation portion 413. The first condensation portion 412 and the second condensation portion 413 are respectively connected to two opposite sides of the heat absorption portion 411.

More specifically, the heat absorption portion 411 is, for example, a flat pipe structure and has two flat surfaces 4111 which are located opposite and parallel to each other. The first condensation portion 412 is a round pipe structure, and the first condensation portion 412 includes a first connection portion 4121 and a first bent portion 4122 connected to each other. The first bent portion 4122 is connected to one side of the heat absorption portion 411 via the first connection portion 4121. The first connection portion 4121 is, for example, parallel to the heat absorption portion 411, and the first bent portion 4122 is, for example, non-parallel to the heat absorption portion 411. In other words, a central line C1 of the first connection portion 4121 is parallel to a central line C2 of the heat absorption portion 411, and a central line C3 of the first bent portion 4122 is non-parallel to the central line C2 of the heat absorption portion 411. For example, the central line C2 of the heat absorption portion 411 passes through the first connection portion 4121 an is overlapped with the central line C1 of the first connection portion 4121, and the central line C3 of the first bent portion 4122 is perpendicular to the central line C2 of the heat absorption portion 411. The second condensation portion 413 is a round pipe structure, and the second condensation portion 413 includes a second connection portion 4131 and a second bent portion 4132. The second bent portion 4132 is connected to another side of the heat absorption portion 411 via the second connection portion 4131. The second connection portion 4131 is, for example, parallel to the heat absorption portion 411, and the second bent portion 4132 is, for example, non-parallel to the heat absorption portion 411. In other words, a central line C4 of the second connection portion 4131 is parallel to the central line C2 of the heat absorption portion 411, and a central line C5 of the second bent portion 4132 is non-parallel to the central line C2 of the heat absorption portion 411. For example, the central line C2 of the heat absorption portion 411 passes through the second connection portion 4131 and is overlapped with the central line C4 of the second connection portion 4131, and the central line C5 of the second bent portion 4132 is perpendicular to the central line C2 of the heat absorption portion 411.

The thermally conductive component 41 is formed by a round pipe with a uniform diameter. Specifically, the heat absorption portion 411, the first connection portion 4121, first bent portion 4122 of the first condensation portion 412, the second connection portion 4131 and the second bent portion 4132 of the second condensation portion 413 are formed by shrinking two opposite ends of the round pipe, flattening the central portion of the round pipe and bending the two opposite ends of the round pipe. In the thermally conductive component 41, the first condensation portion 412 and the second condensation portion 413 are, for example, round pipes with outer diameters D1 and D2, where a width W of the heat absorption portion 411 is, for example, greater than the outer diameter D1 of the first condensation portion 412 and the outer diameter D2 of the second condensation portion 413, and a thickness T of the heat absorption portion 411 is, for example, equal to the outer diameter D1 of the first condensation portion 412 and the outer diameter D2 of the second condensation portion 413. For example, the thickness T of the heat absorption portion 411, the outer diameter D1 of the first condensation portion 412 and the outer diameter D2 of the second condensation portion 413 are 3 mm.

Note that the first condensation portion 412 and the second condensation portion 413 are not restricted to being round pipes and may be modified to pipes with other shapes in some other embodiments. In such a case, a width of the heat absorption portion may be greater than a width of the first condensation portion and a width of the second condensation portion, and the thickness of the heat absorption portion may be equal to a thickness of the first condensation portion and a thickness of the second condensation portion.

The first heat dissipation fin assembly 42 includes a plurality of first fins 421. The first fins 421 are thermally coupled to the first bent portions 4122 of the first condensation portions 412 of the thermally conductive components 41, and the first fins 421 are parallel to one another and are spaced apart from one another. The second heat dissipation fin assembly 43 includes a plurality of second fins 431. The second fins 431 are thermally coupled to the second bent portions 4132 of the second condensation portions 413 of the thermally conductive components 41, and the second fins 431 are parallel to one another and are spaced apart from one another. The first fins 421 and the second fin 431 are, for example, in a plate shape, and the first fins 421 and the second fins 431 are parallel to the central line C2 of the heat absorption portion 411.

The heat absorption portions 411 of the thermally conductive components 41 are mounted into the installation recesses 61 of the metal sheets 60, and the first bent portions 4122 of the first condensation portions 412 and the second bent portions 4132 of the second condensation portions 413 of the thermally conductive components 41 extend towards the support surface 21 of the motherboard 20. In addition, the heat absorption portions 411 of the thermally conductive components 41 and the plate-shaped heat sources 30 are alternately arranged; that is, they are in an interleaved arrangement or a staggered arrangement. The flat surfaces 4111 of the heat absorption portions 411 of the thermally conductive components 41 are connected to the plate-shaped heat sources 30 via the metal sheets 60 and the thermal interface materials 50. In other words, two opposite sides of each the plate-shaped heat source 30 are thermally coupled to the heat absorption portions 411 of two thermally conductive components 41 via the thermal interface materials 50 and the metal sheets 60. As a result, heat generated by the circuit boards 31, the chips 32 and the power management units 33 of the plate-shaped heat sources 30 can be conducted to the heat absorption portions 411 of the thermally conductive components 41, and then heat is conducted to the first fins 421 of the first heat dissipation fin assembly 42 and the second fins 431 of the second heat dissipation fin assembly 43 via the first condensation portions 412 and the second condensation portions 413.

As shown in FIG. 1, the fans 70 are disposed in the accommodation space 11 of the casing 10, and the first heat dissipation fin assembly 42 is located closer to the fans 70 than the second heat dissipation fin assembly 43. The fans 70 are configured to drive air to flow towards to the heat dissipation module 40 for enabling air to perform heat exchange with the first fins 421 and the second fins 431 to take heat away.

In this embodiment, the thermally conductive components 41 includes the heat absorption portions 411 for enabling the heat absorption portions 411 of the thermally conductive components 41 to be alternately arranged with the plate-shaped heat sources 30 arranged compactly and parallel to one another and to be connected to the plate-shaped heat sources 30. Therefore, heat generated by the plate-shaped heat sources 30 can be conducted to the heat absorption portions 411 of the thermally conductive components 41 and then conducted to the first heat dissipation fin assembly 42 and the second heat dissipation fin assembly 43 via the first condensation portions 412 and the second condensation portions 413 of the thermally conductive components 41, such that the first heat dissipation fin assembly 42 and the second heat dissipation fin assembly 43 can perform heat exchange with air via their large surface area so as to take heat away, thereby effectively cooling the plate-shaped heat sources 30. Regarding to a computer simulation result, compared to a case that the plate-shaped heat sources 30 are not provided with the heat dissipation module, the case in this embodiment that the plate-shaped heat sources 30 are provided with the heat dissipation module 40 enables the temperatures of the chips 32 to decrease from 74.8° C. to 62.9° C. and enables the temperature of the power management unit 33 to decrease from 121° C. to 85.8° C.

On the other hand, the first heat dissipation fin assembly 42 and the second heat dissipation fin assembly 43 of the heat dissipation module 40 has large surface areas to contact air, thereby improving overall heat dissipation efficiency of the heat dissipation module 40. Therefore, the chips 32 can operate in an appropriate temperature (e.g., 95° C.) while the fans 70 do not need to operate in full speed. For example, the power consumption of the fans 70 in full speed is 45 watts, but the fans 70 with smaller speed which merely consume 27 watts can enable the chips 32 to operate in the appropriate temperature, thereby approximately saving 40% of power consumption.

Note that the fans 70 are optional components; in some other embodiments, the server may not include fans, and heat absorbed by the heat dissipation module may be dissipated via a nature convection manner.

In this embodiment, the first bent portions 4122 of the first condensation portions 412 and the second bent portions 4132 of the second condensation portions 413 of the thermally conductive components 41 extend toward the support surface 21 of the motherboard 20, which enables the height of the heat dissipation module 40 to be suitable for the height of 1U server 1. Therefore, the heat dissipation module 40 can be fitted in the 1U server 1 with small height.

Note that, in each of thermally conductive components 41, the central line C3 of the first bent portion 4122 of the first condensation portion 412 and the central line C5 of the second bent portion 4132 of the second condensation portion 413 are not restricted to being perpendicular to the central line C2 of the heat absorption portion 411; in some other embodiments, the central line of the first bent portion of the first condensation portion and the central line of the second bent portion of the second condensation portion may be at an acute or obtuse angle to the central line of the heat absorption portion.

In addition, each of the thermally conductive components 41 is not restricted to being integrally a heat pipe. In each of the thermally conductive components of some other embodiments, the heat absorption portion may be a vapor chamber, and the first condensation portion and the second condensation portion may be heat pipes. In such a case, the first connection portion of the first condensation portion and the second connection portion of the second condensation portion may be not connected to two opposite sides of the heat absorption portion along the central line of the heat absorption portion; that is, the central line of the first connection portion of the first condensation portion and the central line of the second connection portion of the second condensation portion may be offset from the central line of the heat absorption portion.

Moreover, in each of thermally conductive components 41, the first condensation portion 412 is not restricted to including both of the first connection portion 4121 and the first bent portion 4122. In some other embodiments, the first condensation portion may merely include the first connection portion or the first bent portion, and the first heat dissipation fin assembly may be disposed on the first connection portion or the first bent portion. Similarly, the second condensation portion may merely include the second connection portion or the second bent portion, and the second heat dissipation fin assembly may be disposed on the second connection portion or the second bent portion.

On the other hand, in each of thermally conductive components 41, the second condensation portion 413 and the second heat dissipation fin assembly 43 are optional components and may be omitted in some other embodiments.

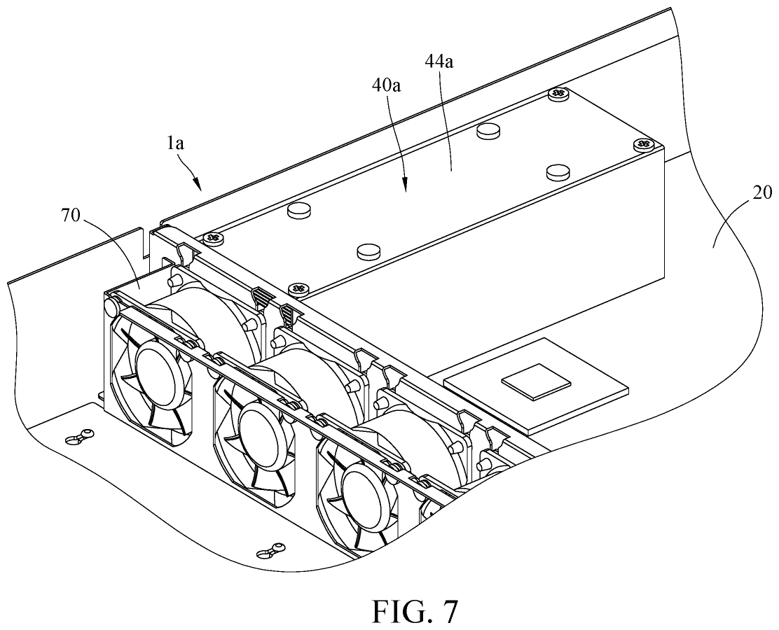

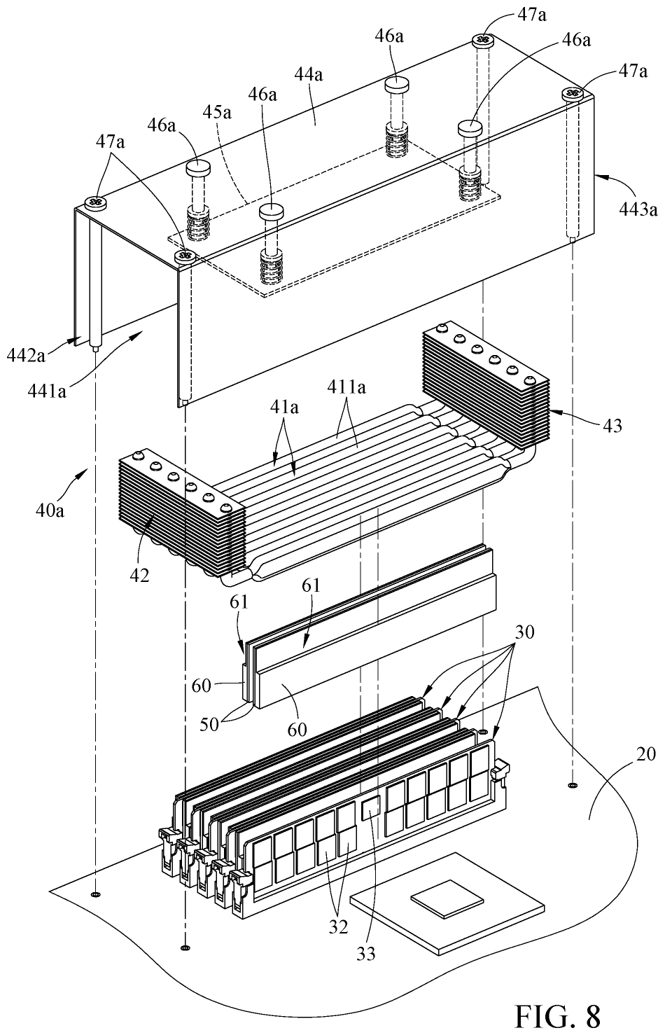

Then, referring to FIGS. 7 and 8, FIG. 7 is a partial perspective view of a server 1a according to a second embodiment of the disclosure, and FIG. 8 is a partial and enlarged exploded view of the server 1a in FIG. 7.

The server 1a of this embodiment is similar to the server 1 of the previous embodiment, and the following descriptions mainly introduce the differences between them, while the same parts between them can be referred to the previous paragraphs and thus will not be repeatedly introduced hereinafter. In addition, the same components in the servers 1 and 1a of this and previous embodiments will use the same reference numerals.

In this embodiment, the server 1a is, for example, a 2U server or a taller server. In addition, a heat dissipation module 40a of the server 1a further includes a wind-guiding cover 44a. The wind-guiding cover 44a is fixed on the motherboard 20, and the plate-shaped heat sources 30, thermally conductive components 41a, the first heat dissipation fin assembly 42 and the second heat dissipation fin assembly 43 are located in the wind-guiding cover 44a.

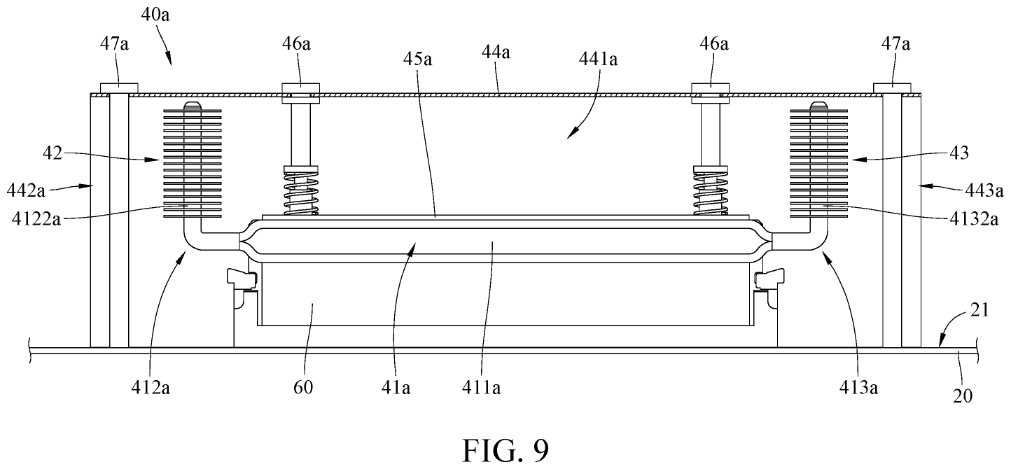

Specifically, referring to FIGS. 8 and 9, FIG. 8 is a partial and enlarged exploded view of the server 1a in FIG. 7, and FIG. 9 is a cross-sectional view of the motherboard 20, the plate-shaped heat sources 30 and the heat dissipation module 40a in FIG. 8.

The wind-guiding cover 44a has a guide channel 441a, an inlet 442a and an outlet 443a, and the inlet 442a and the outlet 443a respectively communicate with two opposite sides of the guide channel 441a. In addition, the heat dissipation module 40a may further include a positioning component 45a, a plurality of pressing components 46a and a plurality of fasteners 47a. The positioning component 45a is, for example, a support plate, and the pressing components 46a are, for example, bolts with springs. The positioning component 45a is located in the guide channel 441a of the wind-guiding cover 44a, and the pressing components 46a are disposed through the wind-guiding cover 44a and are connected to one side of the positioning component 45a. Heat absorption portions 411a of the thermally conductive components 41a are positioned on another side of the positioning component 45a located farther away from the pressing components 46a, such that the thermally conductive components 41a, the first heat dissipation fin assembly 42 and the second heat dissipation fin assembly 43 are located in the guide channel 441a of the wind-guiding cover 44a. The fasteners 47a are, for example, bolts. The wind-guiding cover 44a is placed on the motherboard 20 and is fixed on the motherboard 20 via the fasteners 47a, such that the plate-shaped heat sources 30, the thermal interface materials 50 and the metal sheets 60 are located in the guide channel 441a of the wind-guiding cover 44a, and the heat absorption portions 411a of the thermally conductive components 41a are pressed by the pressing components 46a, such that the heat absorption portions 411a is ensured to be mounted into the installation recesses 61 of the metal sheets 60 for being thermally coupled to the plate-shaped heat sources 30 via the metal sheets 60 and the thermal interface materials 50.

During the installation of the heat dissipation module 40a to the motherboard 20 and the plate-shaped heat sources 30, the thermally conductive components 41a, the first heat dissipation fin assembly 42, the second heat dissipation fin assembly 43, the wind-guiding cover 44a, the positioning component 45a, the pressing components 46a and the fasteners 47a of the heat dissipation module 40a may be assembled with one another as one body in advance. Then, the wind-guiding cover 44a can be placed on the motherboard 20, and the fasteners 47a are screwed into the motherboard 20, such that the heat absorption portions 411a of the thermally conductive components 41a are thermally coupled to the plate-shaped heat sources 30, simultaneously.

Note that the pressing components 46a and the positioning component 45a are optional components. In some other embodiments, the heat dissipation module may not include the pressing components and the positioning component.

In this embodiment, the fans 70 of the server 1a can drive air to flow into the guide channel 441a of the wind-guiding cover 44a through the inlet 442a so as to allow the air to perform heat exchange with the first heat dissipation fin assembly 42 and the second heat dissipation fin assembly 43. Then, the air can flow out of the guide channel 441a of the wind-guiding cover 44a through the outlet 443a so as to take heat away.

In each of the thermally conductive components 41a, the first bent portion 4122a of the first condensation portion 412a and the second bent portion 4132a of the second condensation portion 413a extend away from the support surface 21 of the motherboard 20; that is, the first bent portion 4122a of the first condensation portion 412a and the second bent portion 4132a of the second condensation portion 413a extend upwards relative to the support surface 21 of the motherboard 20. As a result, when the air flows through the first heat dissipation fin assembly 42 and the second heat dissipation fin assembly 43, the airflow is prevented from being interfered by the plate-shaped heat sources 30, thereby facilitating the flowing of the air and improving heat dissipation efficiency. Regarding to a computer simulation result, compared to a case that the plate-shaped heat sources 30 are not provided with the heat dissipation module, the case in this embodiment that the plate-shaped heat sources 30 are provided with the heat dissipation module 40a enables the temperatures of the chips 32 to decrease from 81.1° C. to 58.1° C. and enables the temperature of the power management unit 33 to decrease from 162° C. to 63.9° C.

On the other hand, since the overall heat dissipation efficiency of the heat dissipation module 40a is improved, the chips 32 can operate in an appropriate temperature (e.g., 95° C.) while the fans 70 do not need to operate in full speed. For example, the power consumption of the fans 70 in full speed is 220 watts, but the fans 70 with smaller speed which merely consume 88 watts can enable the chips 32 to operate in the appropriate temperature, thereby approximately saving 60% of power consumption.

In this embodiment, the size of the inlet 442a of the wind-guiding cover 44a may be modified according to actual requirements. For example, the size of the inlet 442a of the wind-guiding cover 44a may be reduced to allow more air to flow through electronic components located outside the wind-guiding cover 44a (e.g., CPU or GPU) for cooling those electronic components.

In this embodiment, the wind-guiding cover 44a, the positioning component 45a, the pressing components 46a, the fasteners 47a, and the first condensation portion 412a and the second condensation portion 413a extending upwards are applied to a 2U server or a taller server, but the disclosure is not limited thereto. In some other embodiments, the heights of the aforementioned components may be modified to allow those components to be applied in a 1U server.

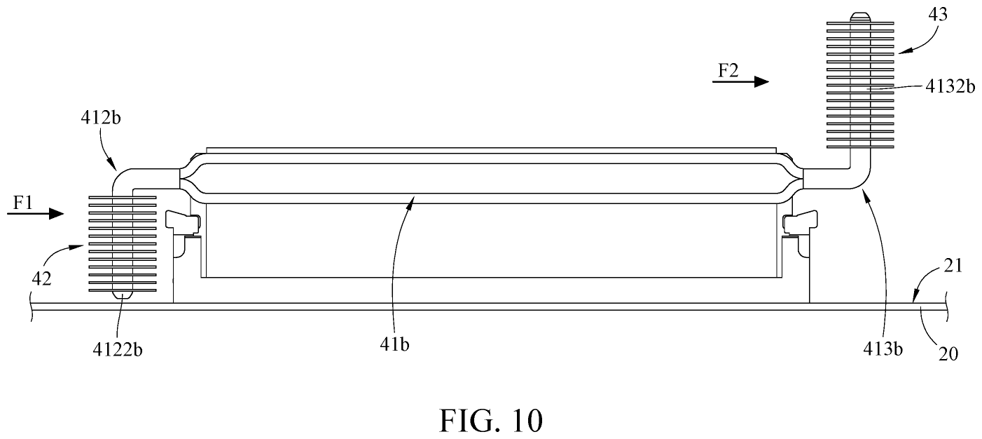

Then, referring to FIG. 10, FIG. 10 is a schematic view of a motherboard 20, a plate-shaped heat source and a heat dissipation module according to a third embodiment of the disclosure.

The thermally conductive component 41b of this embodiment is similar to the thermally conductive component 41a of the previous embodiment, and thus the following descriptions mainly introduce the differences between them, while the same parts between them can be referred to the previous paragraphs and thus will not be repeatedly introduced hereinafter. In addition, the same components in this and previous embodiments will use the same reference numerals.

In this embodiment, a first bent portion 4122b of a first condensation portion 412b of the thermally conductive component 41b extends towards the support surface 21 of the motherboard 20, and a second bent portion 4132b of a second condensation portion 413b of the thermally conductive component 41b extends away from the support surface 21 of the motherboard 20. In other words, the first bent portion 4122b of the first condensation portion 412b extends downwards relative to the support surface 21 of the motherboard 20, and the second bent portion 4132b of the second condensation portion 413b extends upwards relative to the support surface 21 of the motherboard 20. As a result, before an airflow F1 towards the first heat dissipation fin assembly 42 and an airflow F2 towards the second heat dissipation fin assembly 43 respectively reach the first heat dissipation fin assembly 42 and the second heat dissipation fin assembly 43, the airflows F1 and F2 do not pass through any fin assembly, which can ensure the airflows through the first heat dissipation fin assembly 42 and the airflow through the second heat dissipation fin assembly 43 to be cold airflows, thereby improving heat dissipation efficiency.

Note that the first bent portion 4122b of the first condensation portion 412b of the thermally conductive component 41b is not restricted to extending towards the support surface 21 of the motherboard 20, and the second bent portion 4132b of the second condensation portion 413b is not restricted to extending away from the support surface 21 of the motherboard 20. In some other embodiments, the first bent portion of the first condensation portion of the thermally conductive component may extend away from the support surface of the motherboard, and the second bent portion of the second condensation portion may extend towards the support surface of the motherboard.

According to the servers and the heat dissipation modules, the thermally conductive components includes the heat absorption portions for enabling the heat absorption portions of the thermally conductive components to be alternately arranged with the plate-shaped heat sources arranged compactly and parallel to one another and to be connected to the plate-shaped heat sources. Therefore, heat generated by the plate-shaped heat sources can be conducted to the heat absorption portions of the thermally conductive components and then conducted to the first heat dissipation fin assembly via the first condensation portions of the thermally conductive components, such that the first heat dissipation fin assembly can perform heat exchange with air via its large surface area so as to take heat away, thereby effectively cooling the plate-shaped heat sources.

In addition, since the overall heat dissipation efficiency of the heat dissipation module is improved, the chips can operate in the appropriate temperature while the fans do not need to operate in full speed, thereby saving the power consumption.

It will be apparent to those skilled in the art that various modifications and variations can be made to the present disclosure. It is intended that the specification and examples be considered as exemplary embodiments only, with a scope of the disclosure being indicated by the following claims and their equivalents.

What is claimed is:

1. A server, comprising:
a casing;
a motherboard, disposed in the casing;
a plurality of plate-shaped heat sources, separately disposed on the motherboard; and
a heat dissipation module, comprising:
a plurality of thermally conductive components, wherein each of the plurality of thermally conductive components comprises:
a heat absorption portion, wherein the heat absorption portion of each of the plurality of thermally conductive components and the plurality of plate-shaped heat sources are arranged alternately, and the heat absorption portion of each of the plurality of thermally conductive components is connected to the plurality of plate-shaped heat sources; and
a first condensation portion, comprising a first connection portion and a first bent portion, wherein two ends of the first connection portion are respectively connected to the first bent portion and the heat absorption portion; and
a first heat dissipation fin assembly, connected to the first bent portion of the first condensation portion of each of the plurality of thermally conductive components.

2. The server according to claim 1, wherein the plurality of thermally conductive components are heat pipes.

3. The server according to claim 1, wherein the heat dissipation module further comprises a second heat dissipation fin assembly, each of the plurality of thermally conductive components further comprises a second condensation portion, the first condensation portion and the second condensation portion are respectively connected to two opposite sides of the heat absorption portion, and the second heat dissipation fin assembly is connected to the second condensation portion of each of the plurality of thermally conductive components.

4. The server according to claim 3, wherein the second condensation portion comprises a second connection portion and a second bent portion, the first bent portion and the second bent portion are respectively connected to the two opposite sides of the heat absorption portion via the first connection portion and the second connection portion, respectively, the first bent portion and the second bent portion are non-parallel to the heat absorption portion, and the second heat dissipation fin assembly is connected to the second bent portion.

5. The server according to claim 4, wherein the first bent portion and the second bent portion are perpendicular to the heat absorption portion.

6. The server according to claim 4, wherein the motherboard has a support surface, the plurality of plate-shaped heat sources are disposed on the support surface of the motherboard, the plurality of plate-shaped heat sources are parallel to one another, and the first bent portion and the second bent portion extend towards the support surface of the motherboard.

7. The server according to claim 4, wherein the motherboard has a support surface, the plurality of plate-shaped heat sources are disposed on the support surface of the motherboard, the plurality of plate-shaped heat sources are parallel to one another, and the first bent portion and the second bent portion extend away from the support surface of the motherboard.

8. The server according to claim 4, wherein the motherboard has a support surface, the plurality of plate-shaped heat sources are disposed on the support surface of the motherboard, the plurality of plate-shaped heat sources are parallel to one another, the first bent portion extends towards the support surface of the motherboard, and the second bent portion extends away from the support surface of the motherboard.

9. The server according to claim 1, wherein the heat absorption portion is a flat pipe structure, the first condensation portion is a pipe structure, a width of the heat absorption portion is greater than a width of the first condensation portion, and a thickness of the heat absorption portion is equal to a thickness of the first condensation portion.

10. The server according to claim 1, wherein the first heat dissipation fin assembly comprises a plurality of first fins arranged parallel to one another, the heat absorption portion has a central line, the central line passes through the first connection portion of the first condensation portion and is parallel to the plurality of first fins.

11. The server according to claim 1, further comprising at least one fan, wherein the heat dissipation module further comprises a wind-guiding cover, the wind-guiding cover has an inlet and an outlet located opposite to each other, the wind-guiding cover is fixed on the motherboard, the plurality of plate-shaped heat sources, the plurality of thermally conductive components and the first heat dissipation fin assembly are located in the wind-guiding cover, and the at least one fan is disposed in the casing.

12. The server according to claim 11, wherein the heat dissipation module further comprises a positioning component and a plurality of pressing components, the positioning component is disposed in the wind-guiding cover, the heat absorption portion of each of the plurality of thermally conductive components is fixed to the positioning component, the plurality of pressing components are disposed through the wind-guiding cover and are connected to one side of the positioning component located opposite to the heat absorption portion of each of the plurality of thermally conductive components.

13. The server according to claim 1, further comprising a plurality of thermal interface materials and a plurality of metal sheets, wherein each of the plurality of thermal interface materials and each of the plurality of metal sheets are respectively stacked on two opposite sides of each of the plurality of plate-shaped heat sources, each of the plurality of metal sheets has an installation recess, the heat absorption portion of each of the plurality of thermally conductive components is mounted into the installation recess of each of the plurality of metal sheets.

14. The server according to claim 1, wherein the heat absorption portion of each of the plurality of thermally conductive components has two flat surfaces parallel to each other, and the two flat surfaces of the heat absorption portion of each of the plurality of thermally conductive components contact each of the plurality of plate-shaped heat sources.

15. A heat dissipation module, comprising:
a plurality of thermally conductive components, wherein each of the plurality of thermally conductive components comprises:
a heat absorption portion; and
a first condensation portion, comprising a first connection portion and a first bent portion, wherein two ends of the first connection portion are respectively connected to the first bent portion and the heat absorption portion; and
a first heat dissipation fin assembly, connected to the first bent portion of the first condensation portion of each of the plurality of thermally conductive components.

16. The heat dissipation module according to claim 15, further comprising a second heat dissipation fin assembly, wherein each of the plurality of thermally conductive components further comprises a second condensation portion, the first condensation portion and the second condensation portion are respectively connected to two opposite sides of the heat absorption portion, and the second heat dissipation fin assembly is connected to the second condensation portion of each of the plurality of thermally conductive components.

17. The heat dissipation module according to claim 16, wherein the second condensation portion comprises a second connection portion and a second bent portion, the first bent portion and the second bent portion are respectively connected to the two opposite sides of the heat absorption portion via the first connection portion and the second connection portion, respectively, the first bent portion and the second bent portion are non-parallel to the heat absorption portion, and the second heat dissipation fin assembly is connected to the second bent portion.

18. The heat dissipation module according to claim 17, wherein the first bent portion and the second bent portion extend towards a same direction.

19. The heat dissipation module according to claim 17, wherein the first bent portion and the second bent portion extend towards two opposite directions, respectively.

20. The heat dissipation module according to claim 15, wherein the first heat dissipation fin assembly comprises a plurality of first fins arranged parallel to one another, the heat absorption portion has a central line, the central line passes through the first connection portion of the first condensation portion and is parallel to the plurality of first fins.
